(19) United States
(12) Patent Application Publication
(10) Pub. No.: US 2002/0123008 A1
(43) Pub. Date: Sep. 5, 2002

(54) Isotropic etch to form MIM capacitor top plates

(76) Inventor: Xiang J. Ning, Mohegan Lake, NY (US)

Correspondence Address: Siemens Corporation, Intellectual Property Department, 186 Wood Avenue South, Iselin, NJ, 08830, US

(21) Appl. No.: 09/742,644

(22) Filed: Dec. 21, 2000

(51) Int. Cl. G03F 7/00

(52) U.S. Cl. 430/318; 430/313; 430/319; 216/13; 216/41; 216/67

(57) ABSTRACT

A method of fabricating a metal-insulator-metal capacitor (MIMcap) (230), including forming a bottom capacitor plate (210), and depositing a capacitor dielectric (212) over the bottom plate (210). A conductive layer (213) is deposited over the capacitor dielectric (212). A photoresist (216) is deposited over the conductive layer (213). The conductive layer (213) is exposed to an isotropic etchant (224) to form a top capacitor plate (214). Portions (226) of the conductive layer (213) are undercut from beneath the photoresist (216) when forming the top plate (214).

### TECHNICAL FIELD

This invention generally relates to the fabrication of integrated circuits, and more particularly to fabrication of metal-insulator-metal (MIM) capacitors.

### BACKGROUND OF THE INVENTION

Capacitors are used extensively in electronic devices for storing an electric charge. Capacitors essentially comprise two conductive plates separated by an insulator. Capacitors are used in filters, analog-to-digital converters, memory devices, various control applications, and mixed signal and analog devices, for example.

A MIM capacitor (MIMcap) is a particular type of capacitor having two metal plates sandwiched around a capacitor dielectric that is parallel to a semiconductor wafer surface. To form a MIMcap, the top metal plate must be lithographically patterned and then etched. Prior art methods of etching the top metal plate utilize reactive ion etching (RIE). The RIE process should stop upon contact with the capacitor dielectric with minimum erosion of the capacitor dielectric in order to have good reliability performance. Erosion of the capacitor dielectric during the top metal plate RIE has been shown to significantly deteriorate the reliability of a MIMcap.

FIG. 1 shows a cross-sectional view of a prior art MIMcap 130 having a top metal plate 114 formed by RIE. Capacitor dielectric 112 is disposed over bottom plate 110. A metal layer is deposited over the capacitor dielectric 112. A photoresist 116 is deposited over the metal layer, and is lithographically patterned with the desired shape of the top metal plate. The photoresist 116 is then exposed and developed remove exposed portions of the photoresist 116, leaving photoresist 116 portions over the metal layer.

The wafer is exposed to an anisotropic etchant 118 that comprises a gas having molecules that bombard the wafer in a substantially perpendicular direction, as shown. A typical type of anisotropic etch process used is plasma RIE, for example.

The shape and size of top metal plate 114 is very important in the design of a MIMcap 130. The top metal plate 114 determines various perimeters of the MIMcap 130, such as the capacitance value and leakage current, for example. An anisotropic etchant 118 process is used in the prior art because the dimensions of the top plate 114 need to be precisely patterned.

A problem with the MIMcap 130 top plate 114 fabrication process shown in FIG. 1 is that the anisotropic etchant gas 118 produces sidewall-scattered etchants 120 along the side of photoresist 116 and top metal plate 114. This results in the preferential etching of the capacitor dielectric 112 near the top plate 114 to form grooves 122, as shown. The over-etched grooves 122 significantly deteriorate the reliability of the MIMcap 130, because when exposed to high voltages in use, the MIMcap 100 may result in electrical breakdown near the grooves 122. Such electrical breakdown is caused by the thin region of capacitor dielectric 112 underlying grooves 122 suffering fatigue at higher voltages, for example.

Using a plasma RIE etch, it is difficult to control the erosion of the capacitor dielectric 122, especially the thinner the capacitor dielectric 122 is. If the capacitor dielectric 122 is very thin, having a thickness of around 500 Angstroms, for example, the fabrication of the top plate 114 can be particularly problematic. For the proper operation and reliability of the MIMcap 130, the erosion of the capacitor dielectric 122 needs to be controlled to less than 100 Angstroms, for example. It is desired that the remaining capacitor dielectric 122 after the top plate 114 etch process be around 400 Angstroms thick, for example. Frequently, after an anisotropic etch is used, the capacitor dielectric 122 thickness under grooves 122 is less than the desired 400 Angstroms thickness.

What is needed in the art is a MIMcap having a substantially uniform capacitor dielectric 112 and absent the over-etched grooves 122 found in the prior art. A method of forming a top plate of a MIMcap is needed that results in minimal erosion of the capacitor dielectric.

### SUMMARY OF THE INVENTION

The present invention solves these problems of the prior art by providing a method for fabricating a top plate of MIMcap using an isotropic etch process, leaving a substantially planar capacitor dielectric remaining therebeneath.

Disclosed is a method of fabricating a top plate of a metal-insulator-metal capacitor (MIMcap), the MIMcap comprising a bottom plate and a capacitor dielectric disposed over the bottom plate. The method comprises depositing a metal layer over the MIMcap dielectric, and exposing at least the metal layer to an isotropic etchant to form a top plate.

Also disclosed is a method of fabricating a metal-insulator-metal capacitor, comprising forming a bottom metal plate, depositing a capacitor dielectric over the bottom metal plate, depositing a metal layer over the capacitor dielectric, and exposing at least the metal layer to an isotropic etchant to form a top plate.

Further disclosed is a method of fabricating a metal-insulator-metal (MIM) capacitor, comprising forming a bottom conductive plate on a workpiece, depositing a capacitor dielectric over the bottom plate, and depositing a conductive layer over the capacitor dielectric. A photoresist is deposited over the conductive layer, and the photoresist is patterned and etched to leave patterned photoresist remaining over portions of the conductive layer. The conductive layer is exposed to an isotropic etchant to remove exposed portions of the conductive layer.

Advantages of the invention include providing an isotropic downstream plasma etch process for forming MIMcap top capacitor plates, without causing any damage to or over-etching the MIMcap dielectric. This results in a MIMcap having improved reliability compared with MIMcaps of the prior art. A more uniform etching profile of the MIMcap dielectric is provided. The fabrication method disclosed herein also results in a larger process window compared to using plasma RIE.

### BRIEF DESCRIPTION OF THE DRAWINGS

The above features of the present invention will be more clearly understood from consideration of the following descriptions in connection with accompanying drawings in which:

FIG. 1 illustrates a cross-sectional diagram of a prior art MIMcap having a top plate formed by an anisotropic etch process; and

FIGS. 2-4 illustrate cross-sectional views of a MIMcap having a top plate formed by an isotropic etch process in accordance with the present invention in various stages of fabrication.

Corresponding numerals and symbols in the different figures refer to corresponding parts unless otherwise indicated. The figures are drawn to clearly illustrate the relevant aspects of the preferred embodiments, and are not necessarily drawn to scale.

### DETAILED DESCRIPTION OF PREFERRED EMBODIMENTS

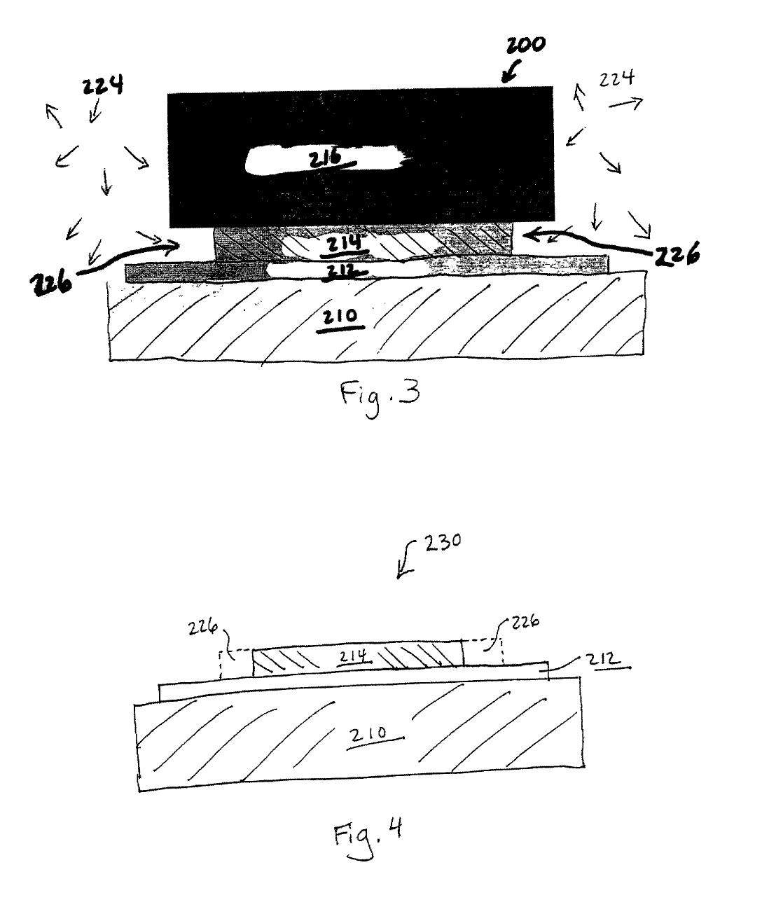

FIGS. 2-4 illustrate cross-sectional views of a MIMcap 230 in accordance with the present invention at various stages of fabrication. A bottom plate 210 is formed on a substrate or a workpiece including component layers, for example (not shown), of a wafer 200. Bottom plate 210 preferably comprises a conductive material such as copper, aluminum, or tungsten, for example, and may alternatively comprise other conductive materials. The substrate or workpiece may include field oxide, active component regions, and/or shallow trench isolation or deep trench isolation regions, not shown.

A dielectric layer is deposited over the bottom plate 210. The dielectric layer preferably comprises silicon dioxide, and alternatively may comprise low or high dielectric constant materials, for example. The dielectric layer is patterned and etched to form capacitor dielectric 212 after the top conductive layer 214 is patterned and etched.

A conductive layer 213 is deposited over the capacitor dielectric 212. A photoresist is deposited over the conductive layer, and is patterned and etched to leave photoresist 216 over the conductive layer 213, as shown. The photoresist pattern 216 is designed to be a predetermined amount larger than the top capacitor plates to be formed. The photoresist 216 preferably comprises an organic polymer commonly used in semiconductor lithography, for example.

In accordance with the present invention, the wafer is exposed to an isotropic etchant 224, preferably comprising a gas, shown in FIG. 3. Because the molecules in the isotropic etchant 224 move about randomly rather than directionally towards the surface of the wafer 200 as in prior art anisotropic etch processes, the isotropic gas 224 bombards the conductive layer 213 not only from the top surface, but also from the conductive layer 213 side surfaces, leaving top capacitor plate 214 having an undercut region 226 beneath the patterned photoresist 216, as shown. The isotropic etch process stops on the MIMcap capacitor dielectric 212 film.

The photoresist 216 is removed to leave the MIMcap 230 in accordance with the present invention, shown in FIG. 4.

Because the etchant gas 224 used in the present invention is isotropic, rather than anisotropic as in the prior art, there is no preferential etching of the capacitor dielectric 212 underlying the top capacitor plate 214. This results in a MIMcap 230 having a uniform capacitor dielectric 212 thickness and improved reliability. The amount 226 of conductive material 213 removed may be determined and controlled by the type of gas used, time exposed, temperature, and pressure, for example.

The isotropic etchant 224 of the present invention preferably comprises a mixture of CF₄, O₂, N₂, and CL₂, as shown in Table 1. Table 1 shows several experimental using a combination and a variety of these chemistries that resulted in successful MIMcap top plate 214 etching in an etch chamber.

TABLE 1
Downstream Plasma Etching Condition

| | | | CF4 | O2 | N2 | Cl2 | | End point | Over etch |
|---|---|---|---|---|---|---|---|---|---|
| Experiment | Temperature | Power | flow | flow | flow | flow | Pressure | Time | Time |
| No. 1 | 130 C. | 700 W | 150 | 60 sccm | 30 sccm | 80 sccm | 30 Pa | 22 sec | 15 sec |
| | | | sccm | | | | | | |
| No. 2 | 130 C. | 700 W | 150 | 60 sccm | 30 sccm | 80 sccm | 30 Pa | 22 sec | 30 sec |
| | | | sccm | | | | | | |
| No. 3 | 130 C. | 700 W | 150 | 60 sccm | 30 sccm | 60 sccm | 30 Pa | 22 sec | 15 sec |
| | | | sccm | | | | | | |
| No. 4 | 130 C. | 700 W | 150 | 60 sccm | 30 sccm | 60 sccm | 30 Pa | 23 sec | 30 sec |
| | | | sccm | | | | | | |
| No. 5 | 130 C. | 700 W | 150 | 60 sccm | 30 sccm | 40 sccm | 30 Pa | 23 sec | 15 sec |
| | | | sccm | | | | | | |
| No. 6 | 130 C. | 700 W | 150 | 60 sccm | 30 sccm | 40 sccm | 30 Pa | 24 sec | 30 sec |
| | | | sccm | | | | | | |

Alternatively, the isotropic etch gas 224 may also include argon and/or BCL₃, for example. More preferably, isotropic etchant gas 224 comprises 150 sccm of CF₄, 60 sccm of O₂, 30 sccm of N₂, and 40-80 sccm of CL₂, as shown in Table 1. Furthermore, the wafer 200 is preferably exposed to the isotropic etchant gas 224 at a temperature of 130° C. at a pressure of 30 Pa, for a duration of an etching time of 37-54 seconds, with an endpoint time of 22-24 seconds, and an over-etch time of 15-30 seconds, for example.

The amount of conductive material 213 etched in the undercut region 226 may be precisely determined and controlled by patterning the photoresist 216 to be larger than the top plate 214 by a predetermined amount equal to the desired size of the undercut region 226. The amount of conductive material 213 etched in the undercut region 226 may also be controlled by the selection of the etchant 224 chemistries and processing parameters, to produce a top capacitive plate 214 having the desired dimensions, for example.

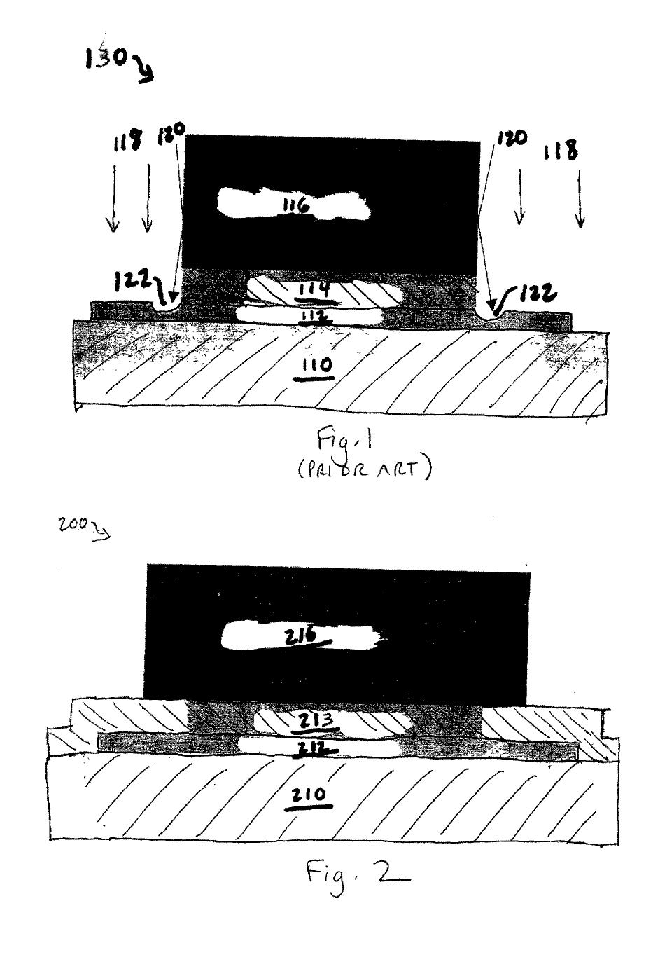

Prior art anisotropic etch processes used to form a top capacitor plate 114 of a MIMcap 130 shown in FIG. 1 typically comprise an RIE, during which a plasma source in a high-power environment generates plasma directly in the presence of the wafer, which is a very active and volatile environment for the semiconductor wafer 100. In contrast, the isotropic etchant gas 224 used to form the top capacitor plate 214 in accordance with the present invention is preferably generated downstream; that is, the plasma for the isotropic etchant gas 224 is generated at a source positioned away from the wafer 200 by a distance, for example, one meter. In this manner, an isotropic etchant gas 224 is produced that effects the wafer 200 surface uniformly rather than being directionally aimed at the wafer 200 causing non-uniform etching of the capacitor dielectric 112 as in the prior art.

The present invention achieves technical advantages as an isotropic downstream plasma etch process for forming MIMcap top capacitor plates 214, without causing any damage to or over-etching the MIMcap dielectric 212. This results in a MIMcap 230 having improved reliability compared with MIMcaps 130 of the prior art. A more uniform etching profile of the MIMcap dielectric 212 is provided. The fabrication method disclosed herein results in a larger process window compared to using plasma RIE.

While the invention has been described with reference to illustrative embodiments, this description is not intended to be construed in a limiting sense. Various modifications in combinations of the illustrative embodiments, as well as other embodiments of the invention, will be apparent to persons skilled in the art upon reference to the description. For example, while a cross-sectional view of the present MIMcap 230 is shown, the MIMcap 230 plates 210 and 214 are preferably square or rectangular, and may run lengthwise along the semiconductor wafer 200 by a distance (not shown) according to the capacitance desired. In addition, the order of process steps may be rearranged by one of ordinary skill in the art, yet still be within the scope of the present invention. It is therefore intended that the appended claims encompass any such modifications or embodiments. Moreover, the scope of the present application is not intended to be limited to the particular embodiments of the process, machine, manufacture, composition of matter, means, methods and steps described in the specification. Accordingly, the appended claims are intended to include within their scope such processes, machines, manufacture, compositions of matter, means, methods, or steps.

What is claimed is:

1. A method of fabricating a top plate of a metal- insulator-metal capacitor (MIMcap), the MIMcap comprising a bottom plate and a capacitor dielectric disposed over the bottom plate, the method comprising:
depositing a conductive layer over the MIMcap dielectric; and
exposing at least the conductive layer to an isotropic etchant to form a top plate.

2. The method according to claim 1 wherein exposing at least the conductive layer to an isotropic etchant includes exposing the capacitor dielectric to the isotropic etchant.

3. The method according to claim 1 further comprising:
depositing a photoresist over the conductive layer; and
patterning the photoresist in a top plate shape, wherein exposing at least the conductive layer to an isotropic etchant comprises undercutting a portion of the top plate sides from beneath the photoresist.

4. The method according to claim 3 wherein patterning the photoresist in a top plate shape comprises patterning the photoresist to a size layer than the top plate.

5. The method according to claim 1 wherein exposing at least the conductive layer to an isotropic etchant comprises exposing the conductive layer to an etchant gas comprising CF₂, O₂, N₂, and Cl₂.

6. The method according to claim 5 wherein exposing at least the conductive layer to an isotropic etchant comprises exposing the conductive layer to an etchant gas comprising argon.

7. The method according to claim 5 wherein exposing at least the conductive layer to an isotropic etchant comprises exposing the conductive layer to an etchant gas comprising BCl₃.

8. The method according to claim 1 wherein depositing a layer comprises depositing a metal, wherein the capacitor dielectric comprises silicon dioxide.

9. The method according to claim 1 wherein exposing the conductive layer to an isotropic etchant comprises exposing the conductive layer to a downstream plasma etch process.

10. A method of fabricating a metal-insulator-metal (MIM) capacitor, comprising:
forming a bottom plate;
depositing a capacitor dielectric over the bottom plate;
depositing a conductive layer over the capacitor dielectric; and
exposing at least the conductive layer to an isotropic etchant to form a top plate.

11. The method according to claim 10 wherein exposing at least the conductive layer to an isotropic etchant includes exposing the capacitor dielectric to the isotropic etchant.

12. The method according to claim 11 wherein exposing at least the conductive layer to an isotropic etchant comprises exposing the conductive layer to a downstream plasma etch process.

13. The method according to claim 12 further comprising:
exposing a photoresist over the conductive layer; and
patterning the photoresist in a top plate shape, wherein exposing at least the conductive layer to an isotropic etchant comprises undercutting a portion of the top plate from beneath the photoresist.

14. The method according to claim 13 wherein exposing at least the conductive layer to an isotropic etchant comprises exposing the conductive layer to an etchant gas comprising CF₂, O₂, N₂, and Cl₂.

15. The method according to claim 14 wherein exposing at least the conductive layer to an isotropic etchant comprises exposing the conductive layer to an etchant gas comprising argon.

16. The method according to claim 14 wherein exposing at least the conductive layer to an isotropic etchant comprises exposing the metal to an etchant gas comprising BCl₃.

17. The method according to claim 14 wherein depositing a conductive layer comprises depositing a metal, wherein the capacitor dielectric comprises silicon dioxide.

18. A method of fabricating a metal-insulator-metal (MIM) capacitor, comprising:
forming a bottom conductive plate on a workpiece;
depositing a capacitor dielectric over the bottom plate;
depositing a conductive layer over the capacitor dielectric;
depositing a photoresist over the conductive layer;
patterning and etching the photoresist to leave patterned photoresist remaining over portions of the conductive layer; and
exposing the conductive layer to an isotropic etchant to remove exposed portions of the conductive layer.

19. The method according to claim 18 wherein exposing the conductive layer to an isotropic etchant comprises undercutting a portion of the conductive layer from beneath the photoresist.

20. The method according to claim 19 further comprising the step of removing the photoresist.

21. The method according to claim 20 wherein exposing at least the conductive layer to an isotropic etchant comprises exposing the conductive layer to an etchant gas comprising CF₂, O₂, N₂, and Cl₂.
